(19) United States
(12) Patent Application Publication
(10) Pub. No.: US 2012/0001312 A1
(43) Pub. Date: Jan. 5, 2012

(54) PACKAGE FOR SEMICONDUCTOR DEVICE, METHOD OF MANUFACTURING THE SAME AND SEMICONDUCTOR DEVICE

(75) Inventors: Masanori Nishino, Kyoto (JP); Hiroshi Horiki, Kyoto (JP)

(73) Assignee: PANASONIC CORPORATION, Osaka (JP)

(21) Appl. No.: 13/165,550

(22) Filed: Jun. 21, 2011

(30) Foreign Application Priority Data
Jun. 29, 2010 (JP) 2010-147011
May 23, 2011 (JP) 2011-114257

(51) Int. Cl. H01L 23/495; H01L 21/56

(52) U.S. Cl. 257/676; 438/123; 257/E23.031; 257/E21.502

(57) ABSTRACT

In a package for a semiconductor device according to the present invention, coating resin 10 covers the boundaries between lead frames 1 and 2 and holding resin 6, at exposed portions in the opening of a resin part 3, thereby closing gaps 18 between the lead frames 1 and 2 and the holding resin 6. Thus it is possible to suppress leakage of molding resin and intrusion of outside air or moisture from the gaps 18 between the lead frames 1 and 2 and the holding resin 6. Particularly, blocking of moisture can prevent the package from being damaged by expansion and contraction of moisture.

### FIELD OF THE INVENTION

The present invention relates to a semiconductor device in which molding resin is provided in a resin part forming the mounting region of a semiconductor element while holding lead frames, and a package used for the semiconductor device.

### BACKGROUND OF THE INVENTION

Referring to FIGS. 7A to 7C, the following will describe a package for a semiconductor device according to the related art.

FIGS. 7A to 7C are schematic drawings showing the configuration of a package for a semiconductor device according to the related art. FIG. 7A is a top view. FIG. 7B is a cross-sectional view taken along line X-X′ of FIG. 7A. FIG. 7C shows the configuration of a semiconductor device using the package for a semiconductor device according to the related art.

As shown in FIGS. 7A to 7C, the package for a semiconductor device according to the related art includes: a lead frame 21 including the mounting region of a semiconductor element on inner leads; a lead frame 22 including a connected region to the semiconductor device on inner leads; a resin part 23 that holds the lead frames 21 and 22 on the top surfaces of the lead frames and opens the mounting region of the semiconductor element; and resin 24 provided on the sides and undersides of the lead frames 21 and 22 to hold the lead frames 21 and 22.

The semiconductor device using the package for a semiconductor device is formed by mounting a semiconductor element 25 on the mounting region of the package for a semiconductor device, connecting the semiconductor element 25 and the connected region via a wire 26, and injecting molding resin 27 into the opening of the resin part 23 so as to mold the semiconductor element 25 and the wire 26.

### DISCLOSURE OF THE INVENTION

In the package for a semiconductor device according to the related art, unfortunately, adhesion may become insufficient between the lead frames 21 and 22 and the resin 24 or the resin part 23. For example, in the formation of the resin 24 or the resin part 23, thermal shrinkage may form a gap 28 between the lead frames 21 and 22 and the resin 24 in a cooling process after the injection of resin. Moreover, a stress such as an external force may form the gap 28 between the lead frames 21 and 22 and the resin 24. In the case where the gap 28 is formed between the lead frames 21 and 22 and the resin 24, the molding resin 27 leaks from the gap 28 during potting of the molding resin 27 in the formation of the semiconductor device. Thus the semiconductor device may have a poor appearance, the opening of the resin part 23 may contain an insufficient amount of the molding resin 27, or a leak of the molding resin 27 may adhere to an external terminal and cause faulty connection or faulty packaging. Moreover, outside air or moisture may enter the molding resin 27 from the gap 28 and generate air bubbles in the molding resin 27 or reduce the humidity resistance of the molding resin 27.

The present invention has been devised to solve the problems. An object of the present invention is to suppress leakage of molding resin and intrusion of outside air or moisture from a gap between lead frames and resin.

In order to attain the object, a package for a semiconductor device according to the present invention includes: at least one first lead frame having an element mounting region on the major surface; at least one second lead frame that has a connected region on the major surface and is electrically isolated; a resin part formed on the major surfaces of the first lead frame and the second lead frame so as to open the element mounting region and the connected region; holding resin provided at least partially on each side of the first and second lead frames with respect to the major surfaces, and in a gap between the first and second lead frames; and a coating covering the boundaries between the first and second lead frames and the holding resin that are exposed from the resin part at least in the opening of the resin part.

Preferably, the coating is formed on the major surface and the back side of the lead frame with respect to the major surface.

Preferably, the coating is a resin coating made of the same material as the resin part and the holding resin.

The coating may be a resin coating made of a different material from the resin part and the holding resin.

The coating may be a non-conductive plate bonded with a non-conductive adhesive.

The coating may be made of a directly applied coating material.

The resin part may be a reflector and the package may be used for an optical semiconductor device.

The resin part may be a reflector, the plate may be a silver plate and the package may be a package for an optical semiconductor device.

The coating exposed in the opening of the resin part may have a surface including asperities.

The asperities may include projections.

The asperities may include recesses.

The asperities may include at least one groove.

A method of manufacturing a package for a semiconductor device according to the present invention, the method including: a die step of placing lead frames in a die; and a resin injecting step of injecting resin into the die to form a resin part that opens an element mounting region, holding resin that holds the lead frames, and coating resin that covers at least the boundaries between the lead frames and the holding resin, wherein the coating resin is formed at least on the boundaries between the holding resin and the lead frames exposed from the resin part at least in the opening of the resin part.

Moreover, a method of manufacturing a package for a semiconductor device according to the present invention, the method including the steps of: resin-molding a resin part that opens an element mounting region and holding resin that holds lead frames; and resin-molding coating resin covering at least the boundaries between the lead frames and the holding resin, wherein the coating resin is formed at least on the boundaries between the holding resin and the lead frames exposed from the resin part at least in the opening of the resin part.

A semiconductor device according to the present invention includes: the package for a semiconductor device; a semiconductor element mounted on the element mounting region; a conductive material electrically connecting the semiconductor element and the connected region; and molding resin that molds the inside of the opening of the resin part.

Moreover, a semiconductor device includes: the package for a semiconductor device; an optical semiconductor element mounted on the element mounting region; a conductive material electrically connecting the optical semiconductor element and the connected region; and translucent resin that molds the inside of the opening of the reflector, wherein the semiconductor device is an optical semiconductor device.

### BRIEF DESCRIPTION OF THE DRAWINGS

FIG. 1A shows the configuration of a package for a semiconductor device according to a first embodiment;

FIG. 1B shows the configuration of the package for a semiconductor device according to the first embodiment;

FIG. 1C shows the configuration of the package for a semiconductor device according to the first embodiment;

FIG. 2A is a process sectional view showing a manufacturing process of the package for a semiconductor device according to the first embodiment;

FIG. 2B is a process sectional view showing the manufacturing process of the package for a semiconductor device according to the first embodiment;

FIG. 2C is a process sectional view showing the manufacturing process of the package for a semiconductor device according to the first embodiment;

FIG. 3A shows the configuration of a package for a semiconductor device according to a second embodiment;

FIG. 3B shows the configuration of the package for a semiconductor device according to the second embodiment;

FIG. 4A is a process sectional view showing a manufacturing process of the package for a semiconductor device according to the second embodiment;

FIG. 4B is a process sectional view showing the manufacturing process of the package for a semiconductor device according to the second embodiment;

FIG. 4C is a process sectional view showing the manufacturing process of the package for a semiconductor device according to the second embodiment;

FIG. 5A shows the configuration of a coating in a package for a semiconductor device according to a third embodiment;

FIG. 5B shows the configuration of the coating in the package for a semiconductor device according to the third embodiment;

FIG. 5C shows the configuration of the coating in the package for a semiconductor device according to the third embodiment;

FIG. 6A shows the configuration of a semiconductor device according to a fourth-embodiment;

FIG. 6B shows the configuration of the semiconductor device according to the fourth embodiment;

FIG. 6C shows the configuration of the semiconductor device according to the fourth embodiment;

FIG. 7A is a schematic drawing showing the configuration of a package for a semiconductor device according to the related art;

FIG. 7B is a schematic drawing showing the configuration of the package for a semiconductor device according to the related art; and

FIG. 7C is a schematic drawing showing the configuration of the package for a semiconductor device according to the related art.

### DESCRIPTION OF THE EMBODIMENTS

### First Embodiment

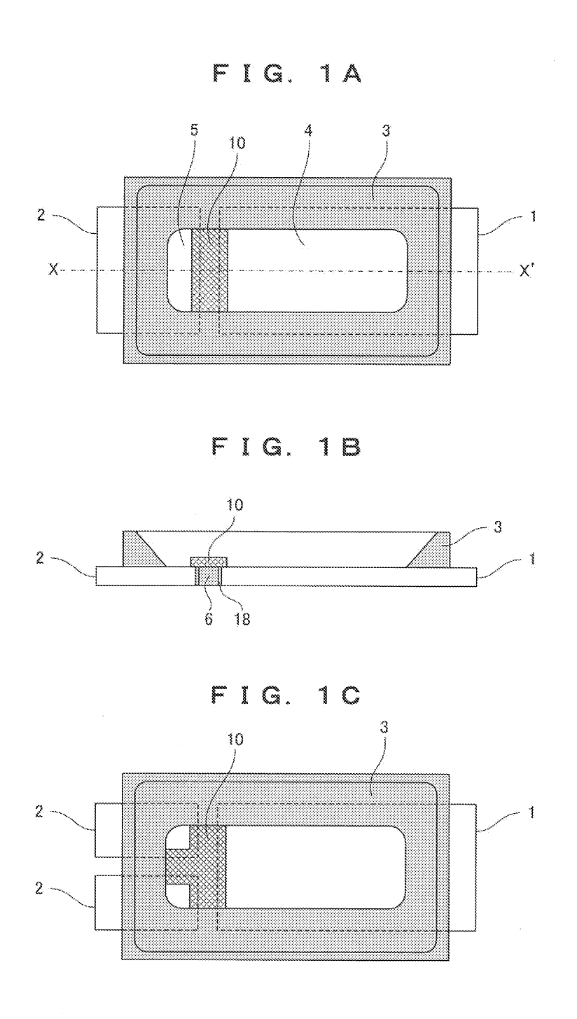

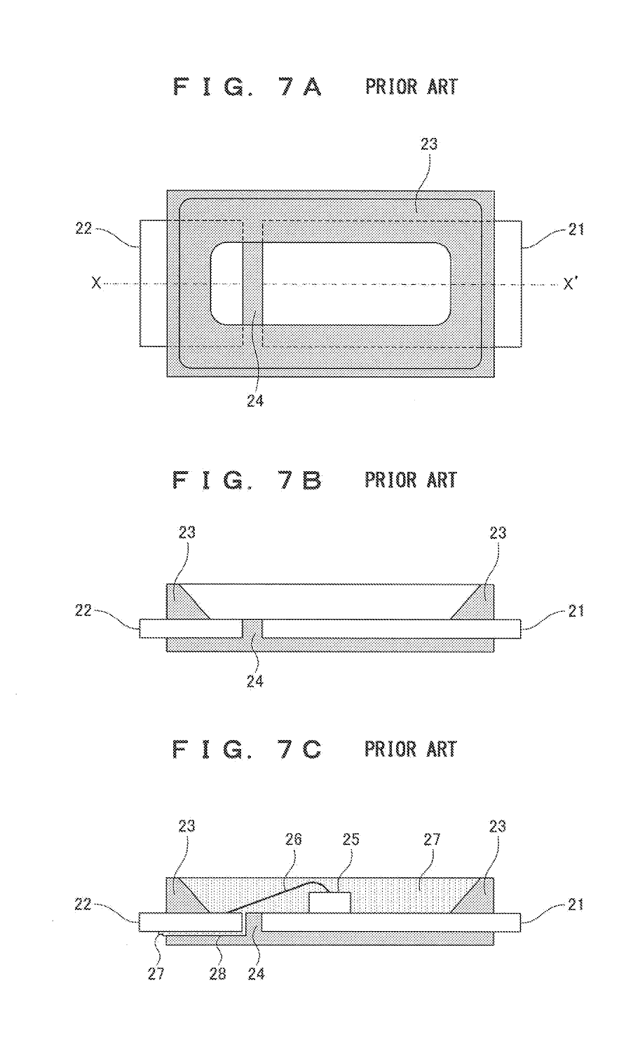

First, referring to FIGS. 1A to 10 and 2A to 2C, the following will describe the configuration and a manufacturing method of a package for a semiconductor device according to a first embodiment.

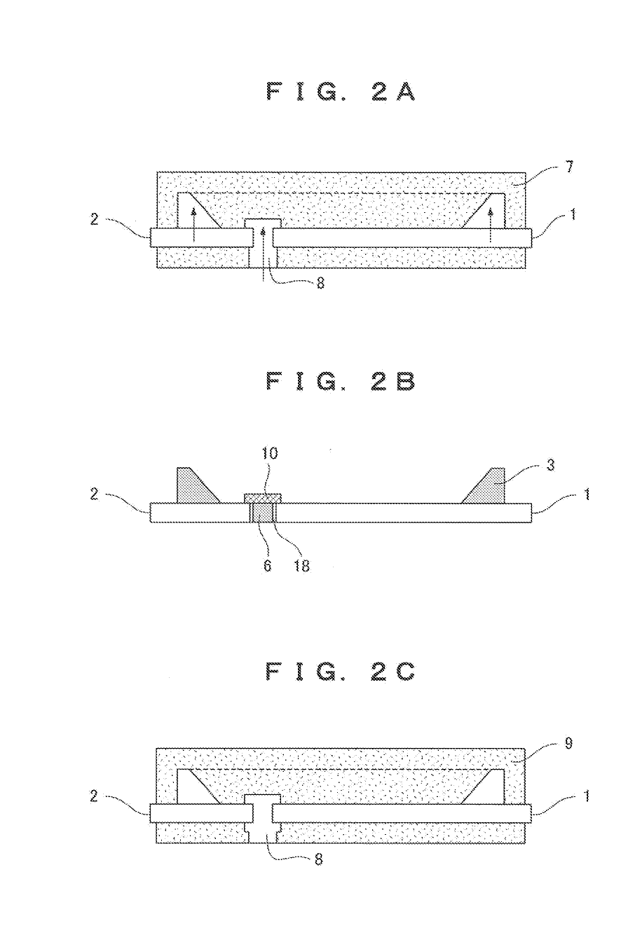

FIGS. 1A to 10 show the configuration of the package for a semiconductor device according to the first embodiment. FIG. 1A is a top view, FIG. 1B is a cross-sectional view taken along line X-X′ of FIG. 1A, and FIG. 10 shows the configuration of a package for a semiconductor device with three terminals. FIGS. 2A to 2C are process sectional views showing the manufacturing process of the package for a semiconductor device according to the first embodiment.

In FIGS. 1A to 10, reference numeral 1 denotes a lead frame including a mounting region 4 of a semiconductor element on inner leads, reference numeral 2 denotes a lead frame including a connected region 5 to a semiconductor device on the inner leads, reference numeral 3 denotes a resin part that is formed on the lead frame 1 and the lead frame 2 to hold the lead frames and surrounds the mounting region 4 and the connected region 5 to protect the regions, reference numeral 6 denotes holding resin that is provided in a gap between the lead frames 1 and 2, on the sides of the lead frames, and optionally on the back sides of the lead frames to hold the lead frames 1 and 2, and reference numeral 10 denotes coating resin provided on the holding resin 6 disposed in the gap between the lead frames 1 and 2, the coating resin 10 completely covering the boundaries between the lead frames 1 and 2 and the holding resin 6. In the package for a semiconductor device according to the present invention, the coating resin 10 covers the boundaries between the holding resin 6 and the lead frames 1 and 2 exposed from the resin part 3 in the opening of the resin part 3, thereby closing gaps 18 between the lead frames 1 and 2 and the holding resin 6. Even if the coating resin 10 thermally contracts, the coating resin 10 contracts in the directions of the lead frames 1 and 2, so that a gap is not formed between the coating resin 10 and the lead frames 1 and 2. As shown in FIGS. 1A to 10, in the opening of the resin part 3, the coating resin 10 may be formed over the holding resin 6 between the lead frames 1 and 2 and may partially cover the lead frames 1 and 2 beyond the boundaries between the lead frames 1 and 2 and the holding resin 6. The coating resin 10 may be formed at least over the boundaries between the lead frames 1 and 2 and the holding resin 6.

In this explanation, the package for a semiconductor device with two terminals has the single lead frame 2. As shown in FIG. 1C, multiple lead frames 2 may be provided. In this case, the coating resin 10 is desirably formed also between the adjacent lead frames 2 so as to cover the boundaries between the holding resin 6 and the lead frames 2 in a region exposed from the resin part 3 in the opening of the resin part 3.

As shown in FIG. 1B, it is desirable to eliminate the holding resin 6 on the back sides of the lead frames 1 and 2 to reduce the thickness of the package for a semiconductor device and increase efficiency of heat dissipation. In the case where the holding powers of the lead frames 1 and 2 have to be increased, the holding resin 6 may be formed on the back sides of the lead frames 1 and 2, also in packages for a semiconductor device according to the following embodiments.

Referring to FIGS. 2A to 2C, the following will describe a method of manufacturing the package for a semiconductor device according to the first embodiment.

First, as shown in FIG. 2A, the lead frames 1 and 2 are placed with a predetermined relationship in a die 7 for forming the resin part 3. In this configuration, the die 7 contains not only the formation regions of the resin part 3 and the holding resin 6 but also a space serving as the formation region of the coating resin 10 on the boundaries between the lead frames 1 and 2 and the holding resin 6. In this state, resin is injected from a resin inlet 8 of the die 7. The injected resin fills a space in the die 7 to form the resin part 3, the holding resin 6, and the coating resin 10.

After that, as shown in FIG. 2B, the resin is cured and then the die 7 is removed, so that the resin part 3 is provided on the lead frames 1 and 2, the lead frames 1 and 2 are held at least by the holding resin 6 and the resin part 3 on the sides of the lead frames 1 and 2 and in the gap between the lead frames 1 and 2, and the coating resin 10 is formed on the boundaries between the lead frames 1 and 2 and the holding resin 6, so that the package for a semiconductor device is completed.

The coating resin 10 is formed thus on the boundaries between the lead frames 1 and 2 and the holding resin 6, at portions exposed from the resin part 3 at least in the opening, thereby closing the gaps 18 disposed between the lead frames 1 and 2 and the holding resin 6 at least at the injection point of the molding resin. Thus when the molding resin is injected into the opening of the resin part 3, it is possible to suppress leakage of the molding resin and intrusion of outside air or moisture into the opening. Particularly, blocking of moisture can prevent the package from being damaged by breakage of the molding resin or the resin part 3 at the expansion and contraction of moisture in the molding resin. In the case where the coating resin 10 is sufficiently strong, the lead frames 1 and 2 with the gaps 18 can have larger holding powers and can be reliably fixed with the resin, improving the accuracy of positioning of a semiconductor element with stable connection.

In this explanation, the coating resin 10 is formed on the major surfaces including the mounting region 4 of the lead frames 1 and 2. The coating resin 10 may be formed on the back sides of the lead frames 1 and 2 with respect to the major surfaces or both surfaces of the lead frames 1 and 2. For example, in the case where the coating resin 10 is formed on both surfaces, the coating resin 10 can be resin-molded with a die 9 shown in FIG. 2C instead of the die 7 in the manufacturing process of FIGS. 2A and 2B.

### Second Embodiment

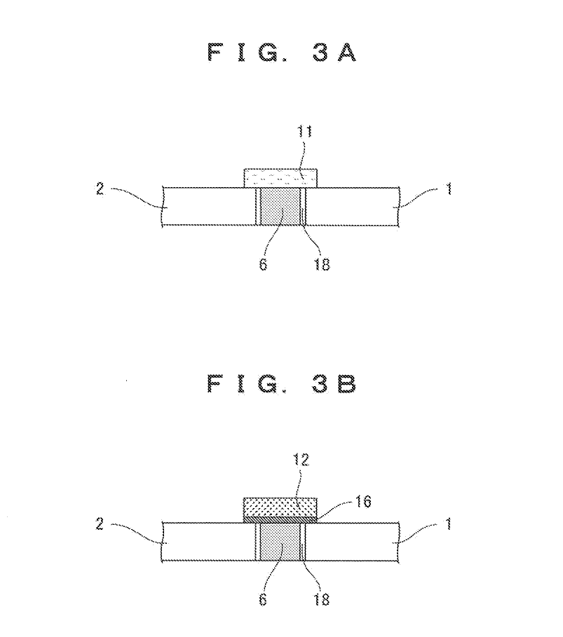

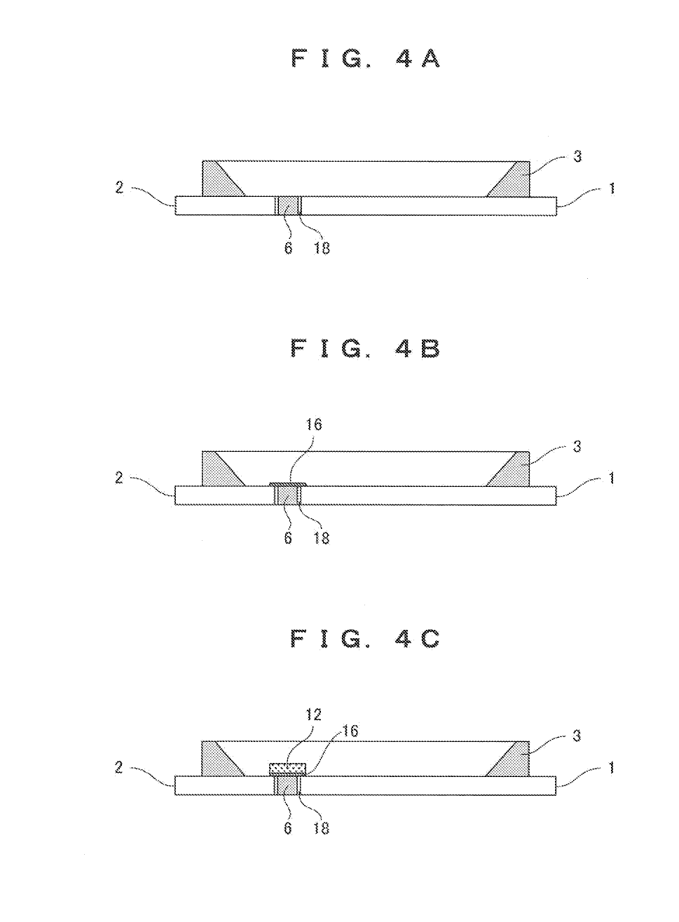

Referring to FIGS. 3A, 3B, and 4A to 4C, the following will describe the configurations and a manufacturing method of a package for a semiconductor device according to a second embodiment.

FIGS. 3A and 3B illustrate the configurations of the package for a semiconductor device according to the second embodiment. FIGS. 3A and 3B show structural examples of a coating. FIGS. 4A to 4C are process sectional views showing the manufacturing process of the package for a semiconductor device according to the second embodiment.

In the first embodiment, the coating resin made of the same resin material as the holding resin 6 and the resin part 3 is formed by resin molding concurrently with the holding resin 6 and the resin part 3. The coating resin 10 may be formed by a different resin molding process. As shown in FIG. 3A, the coating resin 10 may be replaced with coating resin 11 made of a different resin material. The coating resin 11 formed in a different process can be obtained under specifically managed conditions such that the coating resin 11 does not contract in the forming process. Since the coating resin 11 does not have to hold the lead frames 1 and 2, gaps 18 can be coated with a resin material having a small holding power or a less shrinkable material. Thus the gaps 18 can be more reliably closed.

The gaps 18 do not always have to be coated with resin. As shown in FIG. 3B, the gaps 18 may be covered with a non-conductive plate 12 made of materials such as ceramic and plastic. In this case, the holding resin 6 and the resin part 3 are provided on the lead frames 1 and 2 (FIG. 4A), a non-conductive adhesive 16 is applied over the holding resin 6 between the lead frames 1 and 2 and partially covers the lead frames 1 and 2 beyond the boundaries between the lead frames 1 and 2 and the holding resin 6 (FIG. 4B), and the plate 12 is bonded via the adhesive 16 onto a region ranging from the holding resin 6 to the lead frames 1 and 2 (FIG. 4C). In the case where the gaps 18 are covered with the plate 12, it is possible to suppress leakage of molding resin and intrusion of outside air or moisture into the opening of the resin part 3 when the molding resin is injected into the opening.

Furthermore, the gaps 18 may be covered with a coating material that is not permeable to-molding resin and moisture and is directly applied onto the boundaries between the lead frames 1 and 2 and the holding resin 6.

The coating composed of, for example, resin, a plate, or a coating material is provided to cover the gaps 18 on the boundaries between the lead frames 1 and 2 and the holding resin 6, that is, in a region where the gaps 18 are generated, so that the gaps 18 between the lead frames 1 and 2 and the holding resin 6 are closed. This configuration makes it possible to suppress leakage of molding resin and intrusion of outside air or moisture into the opening of the resin part 3 when the molding resin is injected into the opening.

The packages for a semiconductor device according to the first and second embodiments can be used as packages for an optical semiconductor device by replacing the resin part 3 on the top surfaces of the lead frames 1 and 2 with a reflector. In this case, it is preferable that the reflector is made of resin having a high light reflectance or a reflector surface on an element mounting surface is coated with a material having a high light reflectance, thereby improving luminous efficiency. Moreover, the reflector surface on the element mounting surface is preferably inclined to the element mounting surface to improve the luminous efficiency. Moreover, it is also preferable that the coating resin 10 and the coating resin 11 are each made of resin having a high light reflectance and the plate 12 is, for example, a silver plate having a high light reflectance.

### Third Embodiment

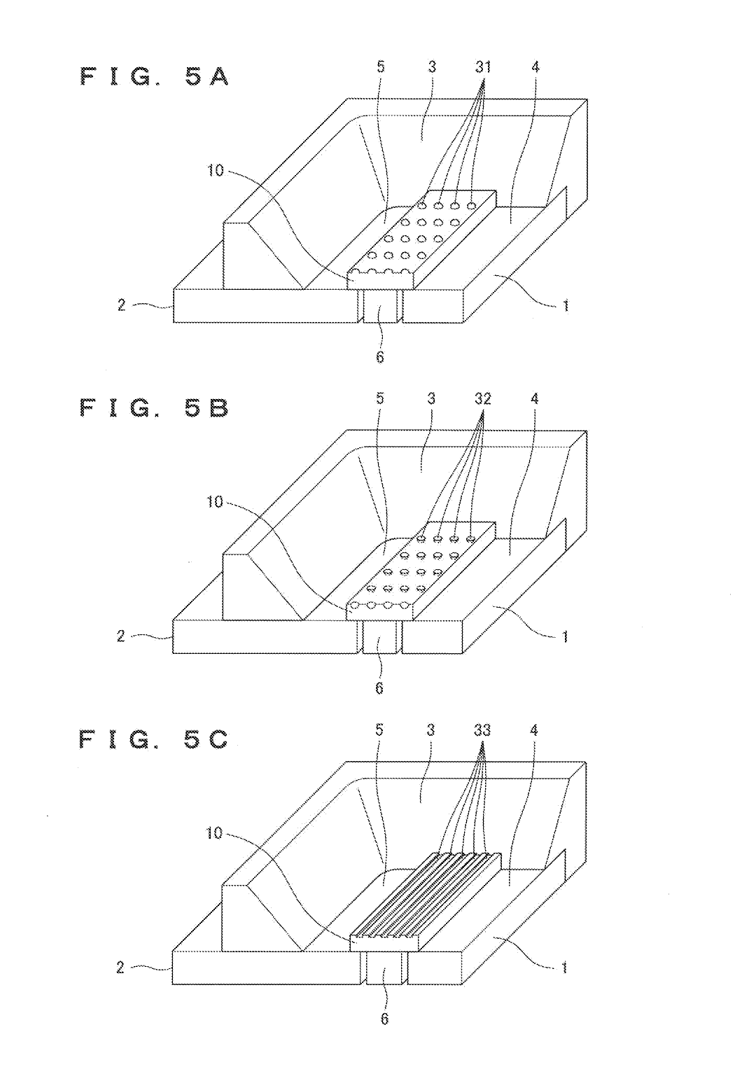

Referring to FIGS. 5A to 5C, the following will describe the configurations of a package for a semiconductor device according to a third embodiment.

FIGS. 5A to 5C show the configurations of a coating in the package for a semiconductor device according to the third embodiment. FIG. 5A is a perspective view illustrating a main part including projecting portions as asperities. FIG. 5B is a perspective view illustrating the main part including recessed portions as asperities. FIG. 5C is a perspective view illustrating the main part including grooves as asperities.

A feature of the package for a semiconductor device according to the third embodiment is the asperities formed on the surface of the coating resin 10 according to the first embodiment or the surface of the coating, for example, the coating resin 11 (hereinafter, see FIG. 3A) or the plate 12 (hereinafter, see FIG. 3B) in the package for a semiconductor device according to the second embodiment.

As shown in FIGS. 5A to 5C, the coating resin 10, the coating resin 11, and the plate 12 are formed so as to cover the boundaries between the lead frames 1 and 2 and the holding resin 6, in the opening of the resin part 3. The asperities are formed on the exposed surface of the coating resin 10, the coating resin 11, or the plate 12 in the opening of the resin part 3. Since the asperities are formed beforehand on the exposed surface of the coating resin 10, the coating resin 11, or the plate 12, a semiconductor device can be mounted in the package for a semiconductor device while suppressing leakage of molding resin and intrusion of outside air or moisture from a gap between the lead frames and the resin. Furthermore, in the case where a region surrounded by the resin part 3 is molded with molding resin, the asperities can increase a contact area between the coating resin 10, the coating resin 11, or the plate 12 and the molding resin and adhesion between the coating resin 10, the coating resin 11, or the plate 12 and the molding resin, thereby preventing the molding resin from peeling off and reliably molding the region with the molding resin.

The asperities may be specifically shaped like, for example, protrusions 31 formed on the surface of the coating resin 10, the coating resin 11 or the plate 12 (FIG. 5A), recesses 32 (FIG. 5B), or at least one groove 33 formed in any directions (FIG. 5C) including a direction parallel to a side of the lead frame 1, the side being opposed to the lead frame 2, a direction orthogonal to the side of the lead frame 1, and combined directions. Alternatively, the protrusions 31, the recesses 32, and the groove 33 may be combined. The protrusions 31 or the recesses 32 may have any shapes including a spherical surface, a prism, and a pyramid, or these shapes may be combined. The protrusions 31 or the recesses 32 may have any sizes and may be uniform or varied in size. Moreover, the protrusions 31 or the recesses 32 may be regularly or irregularly arranged. The grooves 33 may have any sizes and vary in length, width, and depth.

The die 7 of FIG. 2A is shaped to form the asperities, so that the coating resin 10 with the asperities formed on the surface thereof can be formed concurrently with the formation of the resin part 3 and the holding resin 6. Particularly in the case of the plate 12, the asperities may be formed by processing such as cutting and etching after the formation of the plate 12.

In the case of the package for a semiconductor device with the coating resin 11 according to the second embodiment, the asperities formed on the contact surface of the holding resin 6 and the coating resin 11 can improve adhesion between the holding resin 6 and the coating resin 11 and prevent peeling of the coating resin 11.

### Fourth Embodiment

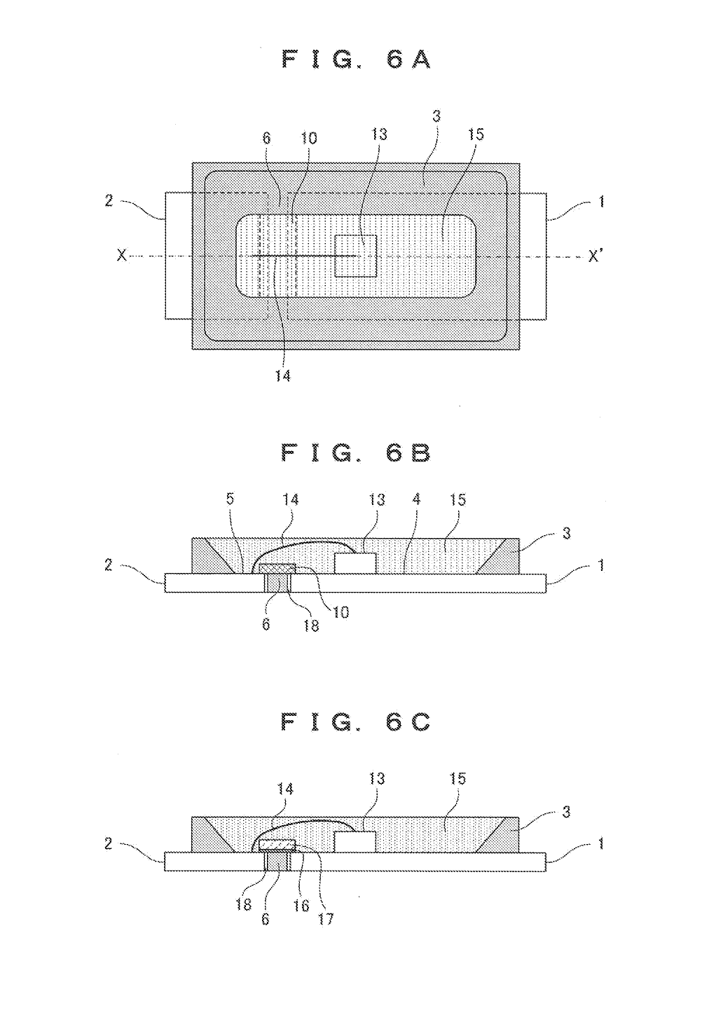

Referring to FIGS. 6A to 6C, the following will describe the configuration of a semiconductor device using the packages for a semiconductor device according to the first to third embodiments.

FIGS. 6A to 6C show the configuration of the semiconductor device according to a fourth embodiment. FIG. 6A is a top view, FIG. 6B is a cross-sectional view taken along line X-X′ of FIG. 6A, and FIG. 6C shows the embodiment using a plate as a coating.

As shown in FIGS. 6A to 6C, the semiconductor device of the fourth embodiment is formed by fixing a semiconductor element 13 with, for example, a conductive adhesive on the mounting region 4 in the packages for a semiconductor device according to the first to third embodiments, electrically connecting the semiconductor element 13 and the connected region 5 via conductive materials including a wire 14, and forming molding resin 15 in a region surrounded by the resin part 3 and the lead frames 1 and 2 such that the semiconductor element 13 and the wire 14 are molded with the molding resin 15. In this case, the use of the package for the semiconductor device in which the back sides of the lead frames 1 and 2 are not coated with resin allows for the quick release of heat generated in an operation of the semiconductor element 13. Additionally, the semiconductor device can be reduced in thickness.

The coating is formed by the coating resin 10 or 11 or the plate 12 (see FIG. 3B and other drawings) on the boundaries between the lead frames 1 and 2 and the holding resin 6, at portions exposed from the resin part 3 at least in the opening of the resin part 3, thereby closing the gaps 18 between the lead frames 1 and 2 and the holding resin 6. Thus it is possible to suppress leakage of the molding resin 15 from the opening of the resin part 3 and intrusion of outside air or moisture into the opening.

An optical semiconductor device may be formed using the package for an optical semiconductor device, an optical semiconductor element serving as the semiconductor element 13, and translucent resin serving as the molding resin 15. In this case, as shown in FIG. 6C, the plate 12 (see FIG. 3B and other drawings) is replaced with a silver plate 17 which reflects light from the optical semiconductor element, thereby improving the luminous efficiency of the optical semiconductor device.

What is claimed is:

1. A package for a semiconductor device, comprising:
at least one first lead frame having an element mounting region on a major surface;
at least one second lead frame that has a connected region on a major surface and is electrically isolated;
a resin part formed on the major surfaces of the first and second lead frames so as to open the element mounting region and the connected region;
holding resin provided at least partially on each side of the first and second lead frames with respect to the major surfaces and in a gap between the first and second lead frames; and
a coating covering boundaries between the first and second lead frames and the holding resin that are exposed from the resin part at least in an opening of the resin part.

2. The package for a semiconductor device according to claim 1, wherein the coating is formed on the major surface and the back side of the lead frame with respect to the major surface.

3. The package for a semiconductor device according to claim 1, wherein the coating is a resin coating made of the same material as the resin part and the holding resin.

4. The package for a semiconductor device according to claim 1, wherein the coating is a resin coating made of a different material from the resin part and the holding resin.

5. The package for a semiconductor device according to claim 1, wherein the coating is a non-conductive plate bonded with a non-conductive adhesive.

6. The package for a semiconductor device according to claim 1, wherein the coating is made of a directly applied coating material.

7. The package for a semiconductor device according to claim 1, wherein the resin part is a reflector and the package is used for an optical semiconductor device.

8. The package for a semiconductor device according to claim 5, wherein the resin part is a reflector, the plate is a silver plate, and the package is used for an optical semiconductor device.

9. The package for a semiconductor device according to claim 1, wherein the coating exposed in the opening of the resin part has a surface including asperities.

10. The package for a semiconductor device according to claim 9, wherein the asperities include projections.

11. The package for a semiconductor device according to claim 9, wherein the asperities include recesses.

12. The package for a semiconductor device according to claim 9, wherein the asperities include at least one groove.

13. A method of manufacturing a package for a semiconductor device, the method comprising:
a die step of placing lead frames in a die; and
a resin injecting step of injecting resin into the die to form a resin part that opens an element mounting region, holding resin that holds the lead frames, and coating resin that covers at least boundaries between the lead frames and the holding resin,
wherein the coating resin is formed at least on the boundaries between the holding resin and the lead frames exposed from the resin part at least in an opening of the resin part.

14. A method of manufacturing a package for a semiconductor device, the method comprising the steps of:
resin-molding a resin part that opens an element mounting region and holding resin that holds lead frames; and
resin-molding coating resin covering at least boundaries between the lead frames and the holding resin,
wherein the coating resin is formed at least on the boundaries between the holding resin and the lead frames exposed from the resin part at least in an opening of the resin part.

15. A semiconductor device comprising:
the package for a semiconductor device according to claim 1;
a semiconductor element mounted on the element mounting region;
a conductive material electrically connecting the semiconductor element and the connected region; and
molding resin that molds inside of the opening of the resin part.

16. A semiconductor device comprising:
the package for a semiconductor device according to claim 7;
an optical semiconductor element mounted on the element mounting region;
a conductive material electrically connecting the optical semiconductor element and the connected region; and
translucent resin that molds inside of an opening of the reflector,
wherein the semiconductor device is an optical semiconductor device.
